(19) United States
(12) Patent Application Publication
(10) Pub. No.: US 2018/0004318 A1
(43) Pub. Date: Jan. 4, 2018

(54) FLEXIBLE SENSOR

(71) Applicants: Khaled Ahmed, Anaheim, CA (US); Prashant Majhi, San Jose, CA (US)

(72) Inventors: Khaled Ahmed, Anaheim, CA (US); Prashant Majhi, San Jose, CA (US)

(21) Appl. No.: 15/200,949

(22) Filed: Jul. 1, 2016

(51) Int. Cl. G06F 3/041; C23C 14/34; H05K 1/09; C23C 16/50; C23C 14/14; H05K 1/02; H01J 37/32; C23C 16/24

(52) U.S. Cl. CPC G06F 3/041; H01J 37/32532; C23C 14/34; C23C 16/24; C23C 16/50; H01J 37/32009; C23C 14/14; H05K 1/0274; H05K 1/09; H01J 2237/3321; H01J 2237/334; G06F 2203/04102; G06F 2203/04103; H05K 2201/0323; H05K 2201/0338; H05K 2201/0341

(57) ABSTRACT

Systems, apparatuses, and/or methods to manufacture and/or implement a sensor film, a composite electrode, and/or a computing device such as a flexible device. The sensor film may include a random network of metal lines and graphene interconnecting the metal lines. The composite electrode may be formed from the sensor film. In addition, the composite electrode may include a first portion including a metal layer in a graphene layer, wherein the metal layer is randomly located in the graphene layer, and a second portion excluding the metal layer and including the graphene layer. The sensor film may be patterned to include any composite electrode configuration, such as an antenna electrode configuration, a touch electrode configuration, and so on. Thus, the flexible device may include a flexible touch screen.

### TECHNICAL FIELD

Embodiments generally relate to a sensor including a transparent conductive film. More particularly, embodiments relate to a flexible sensor including a graphene-metal hybrid transparent conductive film.

### BACKGROUND

Various materials have been evaluated for use in transparent devices, including indium tin oxide (ITO) film, ITO one glass solution (OGS), metal mesh (MM) (e.g., silver, copper, etc.), carbon nanotube (CNT), graphene, silver nanowire (SNW), and so on. Transparent devices may include touch screens that are display overlays which may be pressure-sensitive (e.g., resistive), electrically-sensitive (e.g., capacitive), acoustically-sensitive (e.g., surface acoustic wave), photo-sensitive (e.g., infrared), etc. The effect of such overlays is to allow a display to be used as an input device, with such displays coupled with computers. Presently, the most utilized touch screens are resistive touch screens and capacitive touch screens. Resistive touch sensors may be operated, for example, by detecting flow of current between two electrodes that contact each other due to an externally applied pressure, wherein the two electrodes are separated by a predetermined distance from each another when the pressure is not applied. Flexible displays may be bent, rolled, folded, and/or twisted in many different configurations. Thus, various materials have been evaluated for use in flexible transparent displays.

Adding touch to a flexible display is a relatively large challenge to bringing foldable displays to market. While ITO materials may be implemented in touch screens due to relatively good visibility levels and sheet resistivity (e.g., about 100 Ω/sq to 150 Ω/sq), ITO materials may have relatively low flexibility, relatively low availability, relatively high cost, relatively high brittleness, and/or may require relatively onerous fabrication processes. ITO, for example, is brittle and may crack in a foldable display. Thus, the use of ITO materials may be limited in flexible transparent displays.

Moreover, CNT and graphene materials may not yet be usable as stand-alone electrode materials. For example, semitransparent graphene woven fabrics (GFWs) made by non-monolithic growth-and-transfer of graphene on copper mesh may exhibit relatively high resistance (e.g., about 200 Ω/sq) possibly from formation of microdefects during a transfer process. Accordingly, GFWs may require relatively high current that drives increased power consumption. In addition, MM and SNW materials may have relatively higher visibility levels compared to ITO materials, and/or may not be available for relatively large-scale production. Thus, there is considerable room for improvement to provide a transparent conductive film and/or transparent flexible devices.

### BRIEF DESCRIPTION OF THE DRAWINGS

The various advantages of the embodiments will become apparent to one skilled in the art by reading the following specification and appended claims, and by referencing the following drawings, in which:

FIGS. 1A-1D are block diagrams of examples of a sensor film, a composite electrode, and a computing device according to an embodiment;

FIG. 2 is a flowchart of an example of a method to manufacture a sensor film, a composite electrode, and a computing device according to an embodiment;

FIGS. 3A-3L are block diagrams of examples of structures formed during the manufacture of a sensor film, a composite electrode, and a computing device according to an embodiment; and

FIG. 4 is a block diagram of an example of a computing device according to an embodiment.

### DESCRIPTION OF EMBODIMENTS

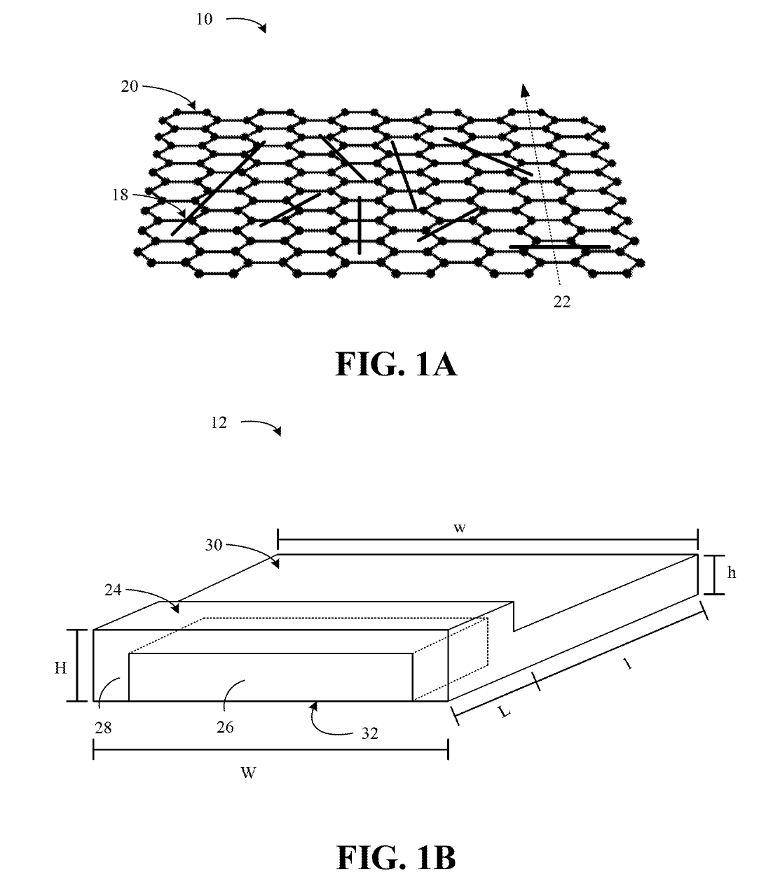

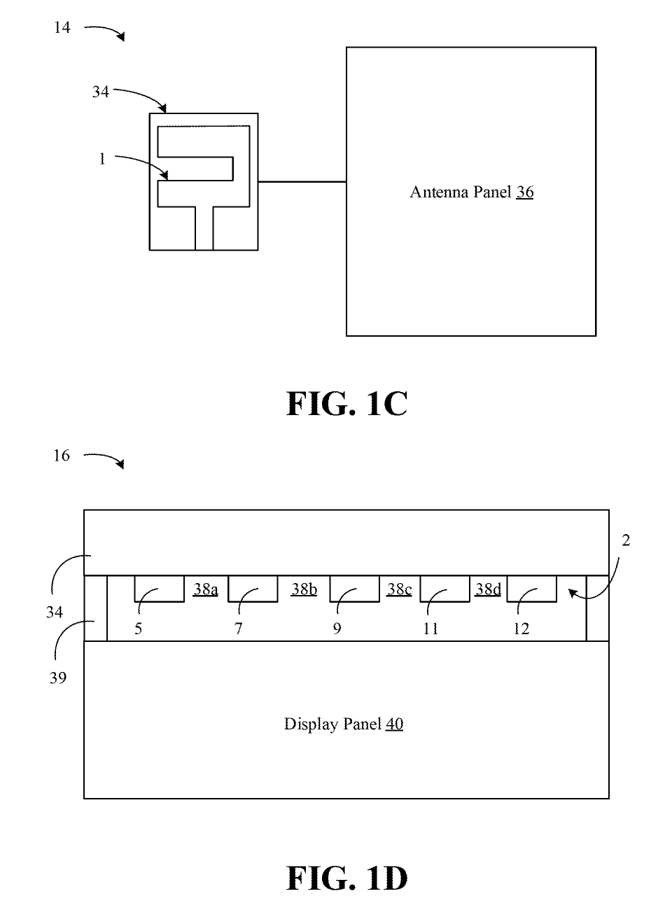

Turning now to FIGS. 1A-1D, a sensor film 10, a composite electrode 12, and flexible devices 14, 16 are shown according to an embodiment. As shown in FIG. 1A, the sensor film 10 includes metal lines 18 that may be composed of a transition metal such as copper, nickel, iridium, ruthenium, and so on. Moreover, the metal lines 18 may be formed to include any morphology. For example, the metal lines 18 may include least two dimensions inside a nanometric size range (e.g., less than about 1 μm), a rectangular cross-sectional shape, a wire form, a rod form, a strip form, and so on. Thus, the metal lines 18 may include one-dimensional (1D) nanostructures having one dimension outside the nanometric size range (e.g., a rectangular nanorod, etc.).

Additionally, at least two of the metal lines 18 may be interconnected by graphene 20. Graphene 20 may include, for example, single-layer graphene (e.g., a fullerene consisting of bonded carbon atoms in sheet form one atom thick), bi-layer graphene (e.g., two monolayers of single-layer graphene), tri-layer graphene (e.g., three monolayers of single-layer graphene), few-layer graphene (e.g., five to ten monolayers of single-layer graphene), or multi-layer graphene (e.g., thick graphene, nanocrystaline thin graphite, twenty to thirty monolayers of single-layer graphene, etc.). Thus, graphene 20 may include a two-dimensional (2D) nanostructure that interconnects the metal lines 18 and that has two dimensions outside the nanometric size range (e.g., a thin film).

In addition, the metal lines 18 may be randomly located in graphene 20. For example, at least two of the metal lines 18 may be randomly distributed in any region of graphene 20. Moreover, at least two of the metal lines 18 may be randomly oriented along any 360° direction perpendicular to one dimension of graphene 20 inside the nanometric size range. Also, at least two of the metal lines 18 may be randomly distributed and/or oriented relative to each other. The largest dimension (e.g., one dimension outside the nanometric size range) of at least two of the metal lines 18 may be located perpendicular to one dimension of graphene 20 inside the nanometric size range.

The sensor film 10 may be processed to form the composite electrode 12. As shown in FIGS. 1A-1B, the sensor film 10 may be patterned along a direction 22 to define the composite electrode 12. As show in FIG. 1B, the composite electrode 12 my include a first portion 24 having a metal layer 26 in a graphene layer 28 and a second portion 30 having only the graphene layer 28. Moreover, the composite electrode 12 may be formed to include any morphology. For example, the composite electrode 12 may include at least two dimensions inside the nanometric size range, a rectangular cross-sectional shape, a wire form, a rod form, a strip form, etc. Thus, the composite electrode 12 may include a 1D nanostructure having one dimension outside the nanometric size range (e.g., a rectangular composite nanofiber, etc.).

In the illustrated example, the first portion 24 includes a height (H) defined by a sum of a vertical thickness (e.g., y-thickness in a Cartesian system) of the metal layer 26 and a vertical thickness of the graphene layer 28 on the metal layer 26, and the second portion 30 includes a height (h) defined by a vertical thickness only of the graphene layer 28. For example, the height H of the first portion 24 may be about 100.5 nm composed a vertical thickness of about 100 nm for the metal layer 26 and a vertical thickness of about 0.5 nm for the graphene layer 28 (e.g., single-layer graphene). In addition, the height h of the second portion 30 may be about 0.5 nm for the graphene layer 28.

Additionally, the first portion 24 includes a length (L) defined by a depth thickness (e.g., z-thickness in a Cartesian system) of the graphene layer 28 on the metal layer 26, and the second portion 30 includes a length (1) defined by a depth thickness of the graphene layer 28 that excludes the metal layer 26. The first portion 26 further includes a width (W) defined by a sum of a horizontal thickness (e.g., x-thickness in a Cartesian system) of the metal layer 26 and a horizontal thickness of the graphene layer 28 on the metal layer 26, and the second portion 30 includes a width (w) defined by a horizontal thickness of the graphene layer 28 that excludes the metal layer 26. As shown in FIG. 1B, H>h, L<1, and W=w at rest.

Fabrication processes (e.g., deposition, growth, patterning, etching, etc.) may, however, be routinely implemented on the sensor film 10 to define H, h, L, l, W, and/or w as desired, including variations within or between portions of the composite electrode 12. For example, the first portion 24 and/or the second portion 30 may have a tapered dimension (e.g., an inter-portion variation to W and/or w) that forms an electrical contact to couple the composite electrode 12 with a voltage driver, a current driver, a signal processor, and so on. In another example, the first portion 24 may include one monolayer of graphene and the second portion 30 may include two or more monolayers of graphene. Similarly, the metal layer 18 may have a height that is the same or different than a height of another metal layer in the composite electrode 12.

In addition, the metal layer 26 may be randomly located in the composite electrode 12. For example, the metal layer 26 may be one of a plurality of metal layers that are randomly distributed in a plurality of regions of the graphene layer 28. In one example, the graphene layer 28 of the second portion 30 may interconnect the metal layer 26 with another metal layer of another portion of the composite electrode 12. Thus, the metal layer 26 and the other metal layer may be spaced apart in the composite electrode 12 by a random length (e.g., the length 1). The metal layer 26 may also be randomly oriented along any 360° direction perpendicular to the height H (e.g., parallel to the length L), which may be the same or different as an orientation of the other metal layer. Thus, the metal layer 26 may be randomly located in the graphene layer 28 relative to one or more other metal layers of the composite electrode 12, relative to one or more other metal layers of another composite electrode from the sensor film 10 formed using the same fabrication parameters, and so on.

Additionally, the composite electrode 12 further includes a surface 32 that is exposed. For example, the surface 32 may be a surface of the metal layer 26 that lacks the graphene layer 28. As shown in FIG. 1B, the surface 32 is located opposite to a surface of the metal layer 28 on which the graphene layer 28 is disposed. The composite electrode 12 may, however, be connected with a material to cover the surface 32. In one example, the surface 32 may be laminated with a graphene layer of another composite electrode to conceal the surface 32. In another example, the surface 32 may be laminated with a similar surface of another composite electrode to conceal the surface 32. In a further example, the composite electrode 12 may be attached with a flexible substrate at a side of the composite electrode 12 having the surface 32. The surface 32 may, however, remain exposed. For example, the composite electrode 12 may be attached with a flexible substrate at a side that is opposite the side having the surface 32.

Notably, the sensor film 10 (and portions thereof) may provide relatively superior properties. For example, graphene may be about 100 times stronger relative to steel with a thickness of about 3.35 Å (about a thickness of a graphene sheet). In addition, the sensor film 10 and/or the composite electrode 12 may be stressed and strained (e.g., bent, folded, stretched, twisted, rolled, etc.) in various implementations without substantial degradation to mechanical, optical, and/or electrical properties. Moreover, graphene may be a relatively efficient conductor of heat, of electricity, and so on. Graphene may also be substantially transparent. Thus, the sensor film 10 (and portions thereof) may provide a sheet resistance of about 1 Ω/sq to about 10 Ω/sq and/or a transmittance of at least about 90%, which is superior relative to ITO films.

As shown in FIG. 1C-1D, the sensor film 10 may be patterned and connected with a flexible substrate 34 to be implemented in the flexible devices 14, 16. The flexible substrate 34 may include, for example, a polymer material such as polyethylene terephthalate (PET), cyclic olefin polymer (COP), cyclic olefin copolymer (COCP), polyimide (PI), polycarbonate (PC), triacetyl cellulose (TAC), and so on. The thickness of the flexible substrate 12 may be controlled. For example, the thickness of the flexible substrate 34 may be between about 10 nm and about 100 nm. The sensor film 10 may, however, also be coupled with a rigid substrate (e.g., glass, etc.) to be implemented in a relatively rigid device such as a rigid antenna device, a rigid touch screen device, etc.

As shown in FIG. 1C, the sensor film 10 may be patterned to include an antenna electrode configuration 1. The antenna electrode configuration 1 may include, for example, a single continuous composite electrode, a plurality of joined individual composite electrodes, and so on. Thus, the sensor film 10 may be implemented as a flexible and/or wearable high efficiency (e.g., >50%) transparent antenna in the flexible device 14. In this regard, the sensor film 10 may be coupled with an antenna panel 36. The antennal panel 36 may include, for example, an amplifier, a converter, a signal processor, and so on.

As shown in FIG. 1D, the sensor film 10 may be patterned to include a touch electrode configuration 2. The touch electrode configuration 2 may include, for example, a plurality of parallel composite electrodes 5, 7, 9, 11, 12 attached to the flexible substrate 34 to form a flexible touch screen of the flexible device 16. In the illustrated example, the sensor film 10 is patterned to include a plurality of gaps 38a-38d that separate respective composite electrodes 5, 7, 9, 11, 12. In addition, a spacer 39 (e.g., an adhesive, etc.) connects the flexible substrate 34 with a display panel 40. The display panel 40 may include, for example, a light filter, a signal processor, and so on.

In one example, the composite electrodes 5, 7, 9, 11, 12 may be implemented as piezoresistive electrodes having a resistance that varies with applied force. In addition, the display panel 38 may include and/or may be coupled with a touch determiner to extract a touch coordinate corresponding to a touch event by a user of the flexible device 16 based on a time delay for a sensing signal that is to be applied to any or all of the composite electrodes 5, 7, 9, 11, 12. The touch determiner may also calculate a touch force corresponding to the touch event by the user based on a resistance value from any or all or the composite electrode 5, 7, 9, 11, 12.

Notably, the relatively low resistivity and high transparency of the sensor film 10 (and portions thereof) may substantially outperform traditional materials in transparent implementations such as in transparent antennas and transparent touch screens. In addition, the mechanical flexibility of the sensor film (and portions thereof), alone or in combination with the flexible substrate 34, may improve the operation of a computing platform, such as a laptop, a personal digital assistant (PDA), a media content player, a mobile Internet device (MID), a computer server, a gaming platform, any smart device such as a wireless smart phone, a smart tablet, a smart TV, a smart watch, and so on. For example, the flexible devices 14, 16 may provide relatively improved sensitivity to local electronic properties without sacrificing mechanical toughness, scratch resistance, optical transparency, resistance to debris (e.g., dirt, dust, oils, moisture, etc.), and so on.

In the illustrated examples, the flexible devices 14, 16 may include communication functionality for a wide variety of purposes such as, for example, cellular telephone (e.g., Wideband Code Division Multiple Access/W-CDMA (Universal Mobile Telecommunications System/UMTS), CDMA2000 (IS-856/IS-2000), etc.), WiFi (Wireless Fidelity, e.g., Institute of Electrical and Electronics Engineers/IEEE 802.11-2007, Wireless Local Area Network/LAN Medium Access Control (MAC) and Physical Layer (PHY) Specifications), LiFi (Light Fidelity, e.g., IEEE 802.15-7, Wireless Local Area Network/LAN Medium Access Control (MAC) and Physical Layer (PHY) Specifications), 4G LTE (Fourth Generation Long Term Evolution), Bluetooth (e.g., IEEE 802.15.1-2005, Wireless Personal Area Networks), WiMax (e.g., IEEE 802.16-2004, LAN/MAN Broadband Wireless LANS), Global Positioning System (GPS), spread spectrum (e.g., 900 MHz), NFC (Near Field Communication, ECMA-340, ISO/IEC 18092), and other radio frequency (RF) purposes.

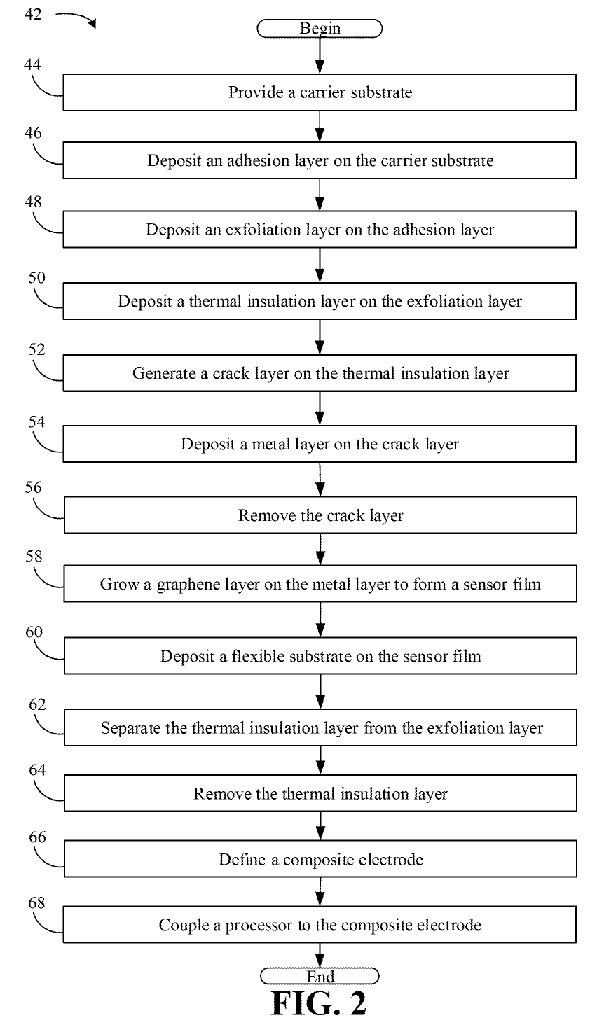

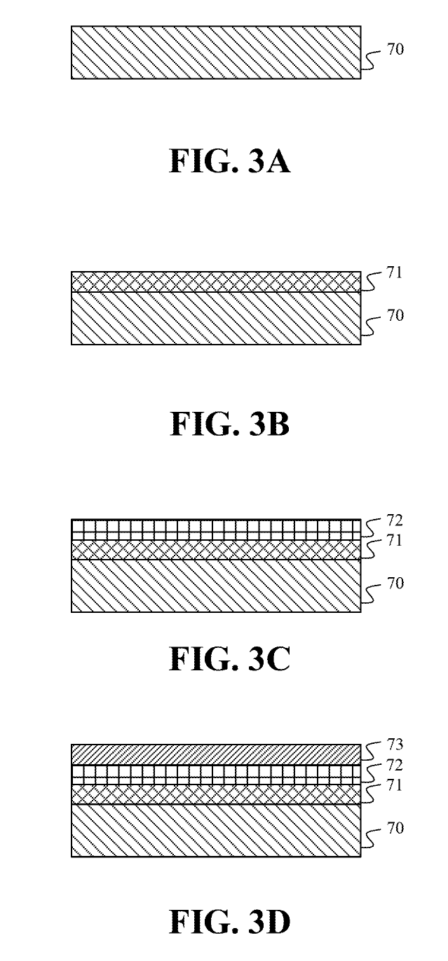

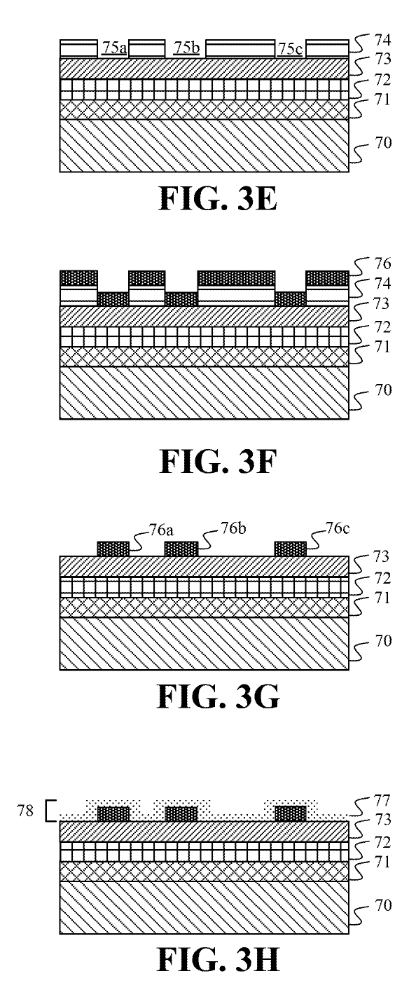

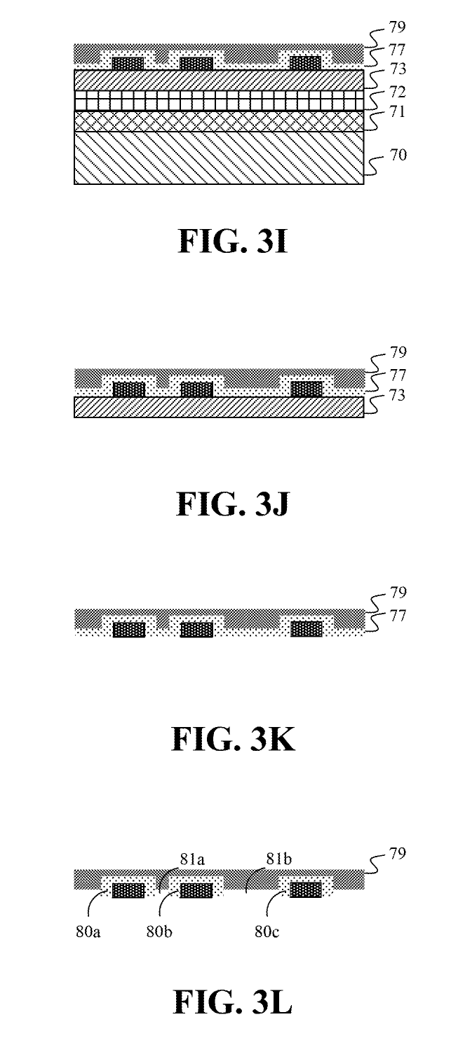

FIG. 2 shows a method 42 to manufacture a sensor film, a composite electrode, and a computing device according to an embodiment. Moreover, FIGS. 3A-3L show examples of structures formed by implementing the method 42. The method 42 may be implemented as a module or related component in a set of logic instructions stored in a non-transitory machine- or computer-readable storage medium such as random access memory (RAM), read only memory (ROM), programmable ROM (PROM), firmware, flash memory, etc., in configurable logic such as, for example, programmable logic arrays (PLAs), field programmable gate arrays (FPGAs), complex programmable logic devices (CPLDs), in fixed-functionality hardware logic using circuit technology such as, for example, application specific integrated circuit (ASIC), complementary metal oxide semiconductor (CMOS) or transistor-transistor logic (TTL) technology, or any combination thereof. For example, computer program code to carry out operations shown in the method 42 may be written in any combination of one or more programming languages, including an object oriented programming language such as JAVA, SMALLTALK, C++ or the like and conventional procedural programming languages, such as the “C” programming language or similar programming languages.

Illustrated processing block 44 in FIG. 2 provides a carrier substrate 70 as shown in FIG. 3A, which may have a relatively large surface area. For example, the carrier substrate 70 may include a glass substrate having a surface area of about 1.4 m by about 1.2 m (e.g., 1.4 m×1.3 m, etc.). The glass substrate may include glass material such as, for example, quartz glass, non-alkali glass, crystallized transparent glass, soda-lime silica glass, chemically strengthened glass, heat strengthened glass, ion-exchange strengthened glass (e.g., potassium ion, alumino-silica, etc.), plastic glass (e.g., isobutyl methacrylate, etc.), sapphire glass, and so on.

Illustrated processing block 46 in FIG. 2 provides for depositing an adhesion layer 71 on the carrier substrate 70 as shown in FIG. 3B. The adhesion layer 71 couples the carrier substrate 70 with one or more other materials. The adhesion layer 71 may include, for example, a silicon-based adhesion layer such as silicon oxide, silicon nitride, and so on. In addition, the adhesion layer 71 may have a thickness (e.g., a vertical thickness) of about 10 nm to about 100 nm. Block 46 may implement, for example, plasma enhanced chemical vapor deposition (PECVD) to deposit the adhesion layer 71. In this regard, a temperature less than about 500° C. may be utilized to minimize temperature-based damage (e.g., warping, etc.) to the carrier substrate 70. Thus, for example, block 46 may implement PECVD at a temperature of 500° C.

Illustrated processing block 48 in FIG. 2 provides for depositing an exfoliation layer 72 on the adhesion layer 71 as shown in FIG. 3C. The exfoliation layer 72 may be used to separate the temporary carrier substrate 70 from one or more materials, discussed below. The exfoliation layer 72 may include, for example, an amorphous silicon (a-Si) layer. In addition, the exfoliation layer 72 may have a thickness (e.g., a vertical thickness) of about 100 nm to about 300 nm. Block 48 may implement, for example, PECVD to deposit the exfoliation layer 72 utilizing a temperature less than about 500° C.

Illustrated processing block 50 in FIG. 2 provides for depositing a thermal insulation layer 73 on the exfoliation layer 72 as shown in FIG. 3D. The composition and/or the thickness of the insulation layer 73 may thermally insulate one or more materials on a side of the insulation layer 73 when a material on an opposing side of the insulation layer 73 is heated. The thermal insulation layer 73 may include, for example, a silicon oxide layer. In addition, the insulation layer 73 may have a thickness (e.g., a vertical thickness) of at least about 1000 nm. Block 48 may implement, for example, PECVD to deposit the exfoliation layer 72 utilizing a temperature less than about 500° C.

Illustrated processing block 52 in FIG. 2 provides for generating a crack layer 74 on the thermal insulation layer 73 as shown in FIG. 3E. The crack layer 74 may be used to form a random network of grooves 75 (75a-75c) that expose the thermal insulation layer 73. In one example, the grooves 75 are U-shaped vias that reveal the thermal insulation layer 73. The crack layer 74 may include, for example, an acrylic layer. Thus, the crack layer 74 may include poly(methyl methacrylate). In addition, the crack layer 74 may have a thickness (e.g., a vertical thickness) that is greater than a thickness of a metal layer to be deposited on the crack layer 74.

Block 52 may implement, for example, lithography-free processes to minimize cost. In one example, block 52 may implement maskless lithography-free micro patterning. For example, block 52 may deposit and dry an acrylic colloidal dispersion on the thermal insulation layer 73 to form the crack layer 74 having the grooves 75. Block 52 may utilize a temperature less than about 500° C. to dry the acrylic colloidal dispersion. Thus, block 52 may implement relatively inexpensive processes to spontaneously form randomly distributed and possibly interconnected cracks.

Illustrated processing block 54 in FIG. 2 provides for depositing a metal layer 76 on the crack layer 74 as shown in FIG. 3F. The metal layer 76 may be used as a seed layer to grow graphene. The metal layer 76 may include, for example, a transition metal such as copper, nickel, and so on. In addition, the metal layer 76 may have a thickness (e.g., a vertical thickness) of less than about 100 nm. Block 48 may implement, for example, vacuum sputtering to deposit the metal layer 76 on the crack layer 74. In this regard, the deposition temperature may be crack-layer dependent.

Block 54 may implement, for example, vacuum sputtering at a temperate of less than about 300° C. to minimize an impact on the crack layer 74 (e.g., an acrylic polymer). Notably, vacuum sputtering may deposit the transition metal in the grooves 75 of the crack layer 74 and on a top surface of the crack layer. Thus, the crack layer 74 may be formed to include a thickness that is greater than a thickness of the metal layer 76 to allow the metal layer 76 in the grooves 75 of the crack layer 74 to be disconnected from the metal layer 74 on the top surface of the crack layer 74. Thus, the metal layer 76 may partially fill the grooves 75 of the of the crack layer 74.

Illustrated processing block 56 in FIG. 2 provides for removing the crack layer 74 as shown in FIG. 3G. Block 56 may, for example, implement wet chemical etching to remove the crack layer 74. In one example, block 56 may implement wet chemical etching using chloroform to remove an acrylic layer. For example, block 56 may submerge the entire stack into chloroform that will react with the crack layer 74 to release the crack layer 74. Notably, the metal layer 76 outside of the grooves 75 located on the crack layer 74 is also released and washed away. Thus, the metal layers 76a-76c that are attached to the thermal insulation layer 73, which remain after wet chemical etching is implemented, provide a random network of metal lines.

Illustrated processing block 58 in FIG. 2 provides for growing a graphene layer 77 on the metal layers 76a-76c to generate a sensor film 78 including a random network of metal lines interconnected by graphene as shown in FIG. 3H. The graphene layer 77 may include, for example, single-layer graphene, bi-layer graphene, tri-layer graphene, few-layer graphene, or multi-layer graphene. Block 58 may implement, for example, CVD to grow the graphene layer 77 (e.g., thermal CVD, PECVD, etc.). PECVD may be carried out at a relatively low temperature for industrial-scale applications. Thus, block 58 may deposit the graphene layer 77 utilizing a temperature less than about 600° C., such as by implementing PECVD at a temperature of less than about 500° C. In addition, PECVD may be implemented in situ to minimize potential oxidation of the metal layers 76a-76c (e.g., oxidation to copper, etc.).

Notably, graphene may be grown on a top surface of the metal layers 76a-76c, on sidewalls of the metal layers 76a-76c, and at an interface between the metal layers 76a-76c and the thermal insulation layer 73. When spacing between the metal layers 76a-76c on the thermal insulation layer 73 is relatively small (e.g., less than about 10 μm), graphene from adjacent metal layers 76a-76c may merge. Thus, the graphene layer 77 may include a continuous film that forms parallel to a plane of the thermal insulation layer 73. Moreover, properties of the graphene layer 77 may be modified based on a number of graphene monolayers that are used to form the graphene layer 77. In one example, one monolayer of graphene with a transmittance of about 97.7% may have a sheet resistivity of about 30 Ω/sq (e.g., assuming carrier concentration of about 10¹² cm⁻²). In another example, four monolayers of graphene with a transmittance of about 90% may provide a resistivity of about 3 Ω/sq, which is about 10 times lower than the best ITO.

Illustrated processing block 60 in FIG. 2 provides for depositing a flexible substrate 79 on the sensor film 78 as shown in FIG. 3I. The flexible substrate 79 may include, for example, polyester, polyethylene napthalate, polyimide, and so on. In addition, the flexible substrate may have a thickness (e.g., a vertical thickness) of about 10 nm to about 100 nm. Block 60 may, for example, implement wet chemical synthesis and/or physical vacuum deposition to deposit the flexible substrate 79. In one example, block 60 may deposit a solution of polyimide acid (PAA) on the graphene layer 77, thermally treat to remove a solvent, and imidize the PAA to form polyimide. In another example, block 60 may evaporate precursors in a relatively high vacuum, deposit the precursors on the graphene layer 77 at a relatively low temperature, and thermally treat at a relatively low temperature. For example, block 60 may deposit the precursors utilizing a temperature less than about 150° C. and thermally treat utilizing a temperature less than about 300° C. for about 15 minutes.

Illustrated processing block 62 in FIG. 2 provides for separating the thermal insulation layer 73 from the exfoliation layer 72 as shown in FIG. 3J. Block 62 may implement, for example, laser lift off (LLO) to separate the thermal insulation layer 73 from the exfoliation layer 72. Generally, LLO may involve selective laser ablation and evaporation of a relatively strongly absorbing interfacial area. In this regard, UV lasers may be used due to relatively short absorption depth (e.g., less than about 300 nm) and LLO separation with relatively short wavelengths may be unnoticed by an adjacent performance determining functional layer such as the sensor film 78 when the thermal insulation layer 73 is implemented (e.g., SiO₂ with thickness of about 1 μm).

Block 62 may, for example, irradiate a surface of the carrier substrate 70 opposite a surface on which the adhesion layer 71 is disposed with a wavelength that can be absorbed by the exfoliation layer 72 (e.g., a UV laser that is pulsed in the ns range with a predetermined number of pulses to generate heat). In this regard, the exfoliation layer 72 (e.g., a-Si) is heated to cause micro-explosions that detach the thermal insulation layer 73 from the exfoliation layer 72, the adhesion layer 71, and the carrier substrate 70. Notably, an oxide may not absorb UV light, and therefore may not be heated by a UV laser, while a relatively lower bandgap material (e.g., a-Si) that is relatively easy to and/or inexpensive to manufacture may absorb UV light from the UV laser to create micro-explosions for detachment. Thus, the exfoliation layer 72 may include a bandgap that allows for relatively efficient absorption (e.g., reaction) with light from a laser beam. In one example, the exfoliation layer 72 may include a bandgap of about 6.2 eV for a 200 nm Excimer laser. In another example, the exfoliation layer 72 may include amorphous silicon with a bandgap of less than about 1.9 eV.

Block 62 may, for example, irradiate an Excimer laser light-beam having a wavelength of about 200 nm to about 308 nm through the carrier substrate 70 (e.g., a temporary glass carrier substrate) and onto exfoliation layer 72 (e.g., a-Si). In this regard, a-Si in a direct vicinity of a glass carrier substrate (e.g., to a depth of 200 nm) may be evaporated by pulses of about 25 ns to about 50 ns using an energy density of about 200 J/cm² to about 300 J/cm². Block 62 may move the temporary carrier substrate 70 under the pulsing laser beam field to span, for example, an entire display panel (730 mm×920 mm). In this regard, about fifty-five displays with a six-inch diagonal may be obtained.

Illustrated processing block 64 in FIG. 2 provides for removing the thermal insulation layer 73 from the sensor film 78 as shown in FIG. 3K. Block 64 may, for example, implement wet chemical etching to remove the thermal insulation layer 73. In one example, block 64 may implement wet chemical etching using dilute hydrofluoric acid (DHF) to remove a SiO₂ layer. In this regard, DHF may be highly selective for SiO₂ and not for graphene. Graphene may be relatively stable in air (e.g., may not oxidize), and therefore may be readily moved, attached, patterned, and so on.

Illustrated processing block 66 in FIG. 2 provides for defining a composite electrode 80 (80a-80b) from the sensor film 78 as shown in FIG. 3L. In one example, a metal fill factor may be less than about 10% of a total area of the flexible substrate 79 with a structural width of about 500 nm to about 1000 nm, a height of about 100 nm, and an average spacing between metal of about 5 μm to about 50 μm. Thus, block 66 may pattern the sensor film 78 in a predetermined electrode configuration (e.g., an antenna electrode configuration, a touch electrode configuration, etc.) to form the composite electrodes 80a-80b each having randomly distributed metal (e.g., relative to each other). Block 66 may, for example, implement O₂ plasma etching to pattern graphene (e.g., power about 50 W to about 150 W and O₂ flow about 20 sccm to about 30 sccm for about 1 minute to about 3 minutes). In addition, block 66 may implement wet chemical etching to pattern metal using ferric chloride (FeCl₃) (e.g., for about 5 minutes to about 15 minutes). Moreover, block 66 may form gaps 81a-81b to separate the composite electrodes 80a-80c.

Illustrated processing block 68 in FIG. 2 provides for coupling a processor with the composite electrodes 80a-80b to from a computing device. In one example, the processor may include an antenna signal processor that is electrically coupled with the sensor film 78 patterned in an antenna electrode configuration. In another example, the processor may include a touch signal processor that is electrically coupled with the sensor film 78 patterned in a touch screen electrode configuration.

For example, the processor may include logic to extract a touch coordinate corresponding to a touch event by a user of the computing device based on a time delay for a sensing signal that is to be applied to any or all of the composite electrodes 80a-80c. The logic may also calculate a touch force corresponding to the touch event by the user based on a resistance value from any or all of the composite electrodes 80a-80c. In addition, the processor may include logic to detect capacitance that may change as a function of proximity or movement of a conductive object (e.g., a finger, a stylus, etc.) to any or all of the composite electrodes 80a-80c that are utilized to detect changes in capacitance (e.g., receive electrode, transmit electrode, etc.). In this regard, a sensor film and/or one or more composite electrodes may be utilized in a surface capacitance touch sensor implementation, a self-capacitance touch sensor implementation, a mutual capacitance touch sensor implementation, and so on.

Accordingly, the computing device may include a touch screen that is pressure sensitive (e.g., resistive), electrically sensitive (capacitive), and so on. The touch screen may include, for example, a glass-only structure, a film-only structure, a glass-and-film structure, an on-cell structure, and so on. The touch screen may include a relatively inflexible touch screen that may not be may subjected to a repeated bending angle (e.g., between about 1 degree and about 160 degrees, or more) with minimized permanent variation from its original state. In this regard, a sensor film and/or one or more composite electrodes may be coupled with a cover-glass substrate including a glass material such as quartz glass, strengthened glass, and so on. In addition, the touch screen may include a flexible touch screen that may be bent, rolled, folded, and/or twisted in may different configurations with minimized permanent variation from its original state. As discussed above, block 60 in FIG. 2 may provide for depositing the flexible substrate 79 on the sensor film 78 such as polyester, polyethylene napthalate, polyimide, and so on, which may be used as a flexible touch screen of a flexible touch device.

While independent blocks and/or a particular order are shown for illustration purposes, it should be understood that one or more of the blocks of the method 42 may be combined, omitted, bypassed, re-arranged, and/or flow in any order. Moreover, one or more of the blocks may implement other fabrication processes such as, for example, roll-to-roll processes, lithography processes, screen printing processes, ink-jet printing processes, lamination processes, pick-and-place processes, polishing processes, and so on. Additionally, parameters of a fabrication process may be routinely changed to provide desired properties, morphologies, and so on. In addition, any or all blocks of the method 42 may be automatically implemented (e.g., without human intervention, etc.).

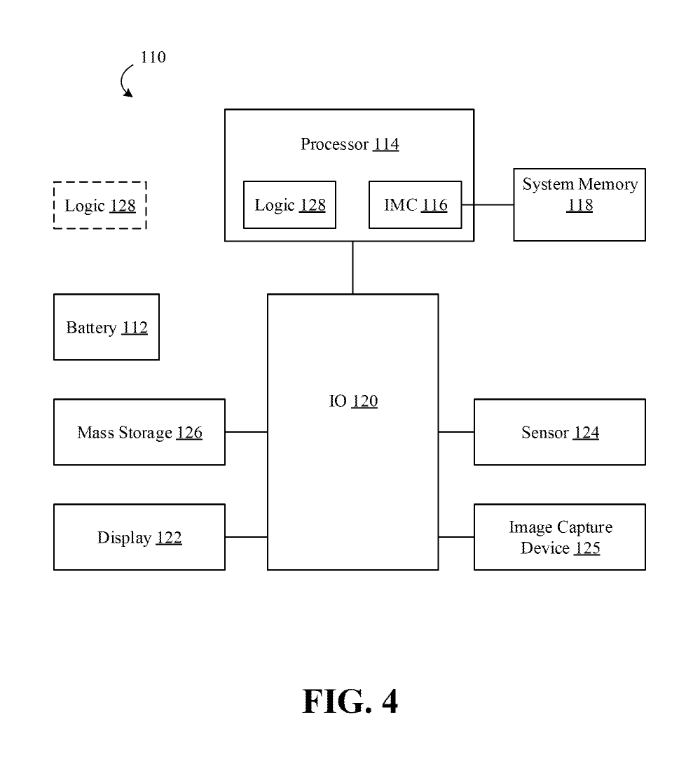

Turning now to FIG. 4, a computing device 110 is shown according to an embodiment. The computing device 110 may be part of a platform having computing functionality (e.g., personal digital assistant/PDA, notebook computer, tablet computer), communications functionality (e.g., wireless smart phone), imaging functionality, media playing functionality (e.g., smart television/TV), wearable functionality (e.g., watch, eyewear, headwear, footwear, jewelry) or any combination thereof (e.g., mobile Internet device/MID). In the illustrated example, the device 110 includes a battery 112 to supply power to the device 110 and a processor 114 having an integrated memory controller (IMC) 116, which may communicate with system memory 118. The system memory 118 may include, for example, dynamic random access memory (DRAM) configured as one or more memory modules such as, for example, dual inline memory modules (DIMMs), small outline DIMMs (SODIMMs), etc.

The illustrated device 110 also includes a input output (TO) module 120, sometimes referred to as a Southbridge of a chipset, that functions as a host device and may communicate with, for example, a display 122 (e.g., touch screen, flexible display, liquid crystal display/LCD, light emitting diode/LED display), a sensor 124 (e.g., touch sensor, an antenna sensor, an accelerometer, GPS, a biosensor, etc.), an image capture device 125 (e.g., a camera, etc.), and mass storage 126 (e.g., hard disk drive/HDD, optical disk, flash memory, etc.). The processor 114 and the IO module 120 may be implemented together on the same semiconductor die as a system on chip (SoC).

The illustrated processor 114 may execute logic 128 (e.g., logic instructions, configurable logic, fixed-functionality logic hardware, etc., or any combination thereof) configured to implement any of the herein mentioned processes and/or technologies, including the sensor film 10, the composite electrode 12, the flexible devices 14, 16 (FIG. 1), one or more blocks of the method 42 (FIG. 2), and/or one or more structures formed by implementing the method 42 (FIGS. 3A-3L), discussed above. In addition, one or more aspects of the logic 128 may alternatively be implemented external to the processor 114. Thus, the computing device 110 may involve the use and/or the manufacture of a sensor film, a composite electrode, a computing device, and so on.

### Additional Notes and Examples

Example 1 may include a sensor film comprising a random network of metal lines, and granphene interconnecting the metal lines.

Example 2 may include the sensor film of Example 1, further including a flexible substrate attached to the sensor film.

Example 3 may include the sensor film of any one of Examples 1 to 2, further including a composite electrode from the sensor film comprising a first portion including a metal layer in a graphene layer, and a second portion excluding the metal layer and including the graphene layer.

Example 4 may include the sensor film of any one of Examples 1 to 3, wherein one or more of the sensor film or the composite electrode is to provide a sheet resistance of about 1 ohm/square to about 10 ohm/square and a transmittance of at least about 90%.

Example 5 may include a composite electrode comprising a first portion including a metal layer in a graphene layer, wherein the metal layer is randomly located in the graphene layer, and a second portion excluding the metal layer and including the graphene layer.

Example 6 may include the composite electrode of Example 5, wherein the metal layer includes a transition metal.

Example 7 may include the composite electrode of any one of Examples 5 to 6, wherein the graphene layer includes single-layer graphene, bi-layer graphene, tri-layer graphene, few-layer graphene, or multi-layer graphene.

Example 8 may include the composite electrode of any one of Examples 5 to 7, further including a gap to separate the composite electrode and another composite electrode located in parallel on a same plane.

Example 9 may include the composite electrode of any one of Examples 5 to 8, further including a flexible substrate attached to the composite electrode.

Example 10 may include the composite electrode of any one of Examples 5 to 9, further including a processor coupled with the composite electrode to form a computing device.

Example 11 may include the composite electrode of any one of Examples 5 to 10, wherein the composite electrode is to form a touch screen of a computing device.

Example 12 may include the composite electrode of any one of Examples 5 to 11, wherein the touch screen is to include a flexible touch screen.

Example 13 may include the composite electrode of any one of Examples 5 to 12, wherein the composite electrode is to provide a sheet resistance of about 1 ohm/square to about 10 ohm/square and a transmittance of at least about 90%.

Example 14 may include at least one computer readable storage medium comprising a set of instructions, which when executed by a device, cause the device to deposit an adhesion layer on a carrier substrate, deposit an exfoliation layer on the adhesion layer, deposit a thermal insulation layer on the exfoliation layer, generate a crack layer on the thermal insulation layer, deposit a metal layer on the crack layer, remove the crack layer, and grow a graphene layer on the metal layer to generate a sensor film including a random network of metal lines interconnected by graphene.

Example 15 may include the at least one computer readable storage medium of Example 14, wherein the instructions, when executed, cause the device to deposit a silicon-based adhesion layer on a glass carrier substrate, deposit an amorphous silicon layer on the silicon-based adhesion layer, deposit a silicon oxide layer on the amorphous silicon layer, deposit an acrylic layer on the silicon oxide layer, and deposit a transition metal on the acrylic layer.

Example 16 may include the at least one computer readable storage medium of any one of Examples 14 to 15, wherein the instructions, when executed, cause the device to implement plasma enhanced chemical vapor deposition (PECVD) to provide one or more of the silicon-based adhesion layer, the amorphous silicon layer, the silicon oxide layer, or the graphene layer at a temperate of less than about 500° C., implement lithography-free micro patterning to deposit and dry an acrylic colloidal dispersion on the silicon oxide layer to form the acrylic layer including a random network of grooves that expose the silicon oxide layer, implement vacuum sputtering to deposit the transition metal on the acrylic layer, and implement wet chemical etching using chloroform to remove the acrylic layer.

Example 17 may include the at least one computer readable storage medium of any one of Examples 14 to 16, wherein the glass carrier substrate has a surface area of about 1.4 m by about 1.2 m, the silicon-based adhesion layer has a thickness of about 10 nm to about 100 nm, the amorphous silicon layer has a thickness of about 100 nm to about 300 nm, the silicon oxide layer has a thickness of at least about 1000 nm, the acrylic layer has a crack including a thickness greater than a thickness of the metal layer, the metal layer has a thickness of less than about 100 nm, and the graphene layer includes single-layer graphene, bi-layer graphene, tri-layer graphene, few-layer graphene, or multi-layer graphene.

Example 18 may include the at least one computer readable storage medium of any one of Examples 14 to 17, wherein the metal layer includes copper or nickel, and wherein the silicon-based adhesion layer includes silicon oxide or silicon nitride.

Example 19 may include the at least one computer readable storage medium of any one of Examples 14 to 18, wherein the instructions, when executed, cause the device to deposit a flexible substrate on the sensor film, separate the thermal insulation layer from the exfoliation layer, and remove the thermal insulation layer from the sensor film.

Example 20 may include the at least one computer readable storage medium of any one of Examples 14 to 19, wherein the instructions, when executed, cause the device to implement laser lift off to heat the exfoliation layer and separate the thermal insulation layer.

Example 21 may include the at least one computer readable storage medium of any one of Examples 14 to 20, wherein the instructions, when executed, cause the device to implement wet chemical synthesis or physical vacuum deposition to deposit polyester, polyethylene napthalate, or polyimide on the sensor film, and implement wet chemical etching using dilute hydrofluoric acid to remove the thermal insulation layer.

Example 22 may include the at least one computer readable storage medium of any one of Examples 14 to 21, wherein the instructions, when executed, cause the device to define a composite electrode from the sensor film.

Example 23 may include the at least one computer readable storage medium of any one of Examples 14 to 22, wherein the instructions, when executed, cause the device implement O₂ plasma etching and wet chemical etching to define the composite electrode from the sensor film.

Example 24 may include the at least one computer readable storage medium of any one of Examples 14 to 23, wherein the instructions, when executed, cause the device to form a gap to separate the composite electrode from another composite electrode located in parallel on a same plane.

Example 25 may include the at least one computer readable storage medium of any one of Examples 14 to 24, wherein the instructions, when executed, cause the device to couple a processor with a portion of the sensor film to form a computing device.

Example 26 may include the at least one computer readable storage medium of any one of Examples 14 to 25, wherein one or more of the sensor film or the composite electrode is to provide a sheet resistance of about 1 ohm/square to about 10 ohm/square and a transmittance of at least about 90%.

Example 27 may include a method to manufacture a sensor film comprising depositing an adhesion layer on a carrier substrate, depositing an exfoliation layer on the adhesion layer, depositing a thermal insulation layer on the exfoliation layer, generating a crack layer on the thermal insulation layer, depositing a metal layer on the crack layer, removing the crack layer, and growing a graphene layer on the metal layer to generate a sensor film including a random network of metal lines interconnected by graphene.

Example 28 may include the method of Example 27, further including depositing a silicon-based adhesion layer on a glass carrier substrate, depositing an amorphous silicon layer on the silicon-based adhesion layer, depositing a silicon oxide layer on the amorphous silicon layer, depositing an acrylic layer on the silicon oxide layer, and depositing a transition metal on the acrylic layer.

Example 29 may include the method of any one of Examples 27 to 28, further including implementing plasma enhanced chemical vapor deposition (PECVD) to provide one or more of the silicon-based adhesion layer, the amorphous silicon layer, the silicon oxide layer, or the graphene layer at a temperate of less than about 500° C., implementing lithography-free micro patterning to deposit and dry an acrylic colloidal dispersion on the silicon oxide layer to form the acrylic layer including a random network of grooves that expose the silicon oxide layer, implementing vacuum sputtering to deposit the transition metal on the acrylic layer, and implementing wet chemical etching using chloroform to remove the acrylic layer.

Example 30 may include the method of any one of Examples 27 to 29, wherein the glass carrier substrate has a surface area of about 1.4 m by about 1.2 m, the silicon-based adhesion layer has a thickness of about 10 nm to about 100 nm, the amorphous silicon layer has a thickness of about 100 nm to about 300 nm, the silicon oxide layer has a thickness of at least about 1000 nm, the acrylic layer has a crack including a thickness greater than a thickness of the metal layer, the metal layer has a thickness of less than about 100 nm, and the graphene layer includes single-layer graphene, bi-layer graphene, tri-layer graphene, few-layer graphene, or multi-layer graphene.

Example 31 may include the method of any one of Examples 27 to 30, wherein the metal layer includes copper or nickel, and wherein the silicon-based adhesion layer includes silicon oxide or silicon nitride.

Example 32 may include the method of any one of Examples 27 to 31, further including depositing a flexible substrate on the sensor film, separating the thermal insulation layer from the exfoliation layer, and removing the thermal insulation layer from the sensor film.

Example 33 may include the method of any one of Examples 27 to 32, further including implementing laser lift off to heat the exfoliation layer and separate the thermal insulation layer.

Example 34 may include the method of any one of Examples 27 to 33, further including implementing wet chemical synthesis or physical vacuum deposition to deposit polyester, polyethylene napthalate, or polyimide on the sensor film, and implementing wet chemical etching using dilute hydrofluoric acid to remove the thermal insulation layer.

Example 35 may include the method of any one of Examples 27 to 34, further including defining a composite electrode from the sensor film.

Example 36 may include the method of any one of Examples 27 to 35, further including implementing O₂ plasma etching and wet chemical etching to define the composite electrode from the sensor film.

Example 37 may include the method of any one of Examples 27 to 36, further including forming a gap to separate the composite electrode from another composite electrode located in parallel on a same plane.

Example 38 may include the method of any one of Examples 27 to 37, further including coupling a processor with a portion of the sensor film to form a computing device.

Example 39 may include the method of any one of Examples 27 to 38, wherein one or more of the sensor film or the composite electrode is to provide a sheet resistance of about 1 ohm/square to about 10 ohm/square and a transmittance of at least about 90%.

Example 40 may include an apparatus to manufacture a sensor film comprising means for performing the method of any one of Examples 27 to 39.

Thus, techniques described herein provide graphene-based sensors, which may be implemented and/or fabricated on relatively large sized substrates, and which may be relatively flexible and/or high quality (e.g., sensitive and do not degrade in quality or performance as it is bent, provides relatively low resistance, etc.). In this regard, a transparent conductive film with transparency greater than about 90% and a sheet resistance of less than about 1 Ω/sq on flexible substrates may be applied to a variety of flexible electronics such as high efficiency transparent antennas, touch and gesture control devices, and so on. The transparent conductive film may be coupled with a flexible substrate to provide a smart self-sensing resistive sensor for sensing touch, applied force, and so on.

Embodiments may also involve depositing one or more materials at a relatively low temperature (e.g., about 500° C.). In addition, embodiments may involve maskless lithography-free micro patterning to provide a random network of cracks that may be used to form a random network of metal lines. Embodiments may also involve depositing a laser-reactive exfoliation layer on a rigid substrate (e.g. 1.4 m² glass), fabricating a thin film transparent conductive film on the exfoliation layer, and depositing a flexible substrate on the transparent conductive film. LLO may be implemented to irradiate a laser-light beam through the back of the glass substrate to cause the transparent conductive film to be separated from the glass substrate as a result of the reaction between the laser-light beam and the exfoliation layer.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the computing system within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” or “at least one of” may mean any combination of the listed terms. For example, the phrases “one or more of A, B or C” may mean A; B; C; A and B; A and C; B and C; or A, B and C. In addition, a list of items joined by the term “and so on” or “etc.” may mean any combination of the listed terms as well any combination with other terms.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A sensor film comprising:
a random network of metal lines, and
granphene interconnecting the metal lines.

2. The sensor film of claim 1, further including a flexible substrate attached to the sensor film.

3. The sensor film of claim 1, further including a composite electrode from the sensor film comprising:
a first portion including a metal layer in a graphene layer, and
a second portion excluding the metal layer and including the graphene layer.

4. The sensor film of claim 3, wherein one or more of the sensor film or the composite electrode is to provide a sheet resistance of about 1 ohm/square to about 10 ohm/square and a transmittance of at least about 90%.

5. A composite electrode comprising:
a first portion including a metal layer in a graphene layer, wherein the metal layer is randomly located in the graphene layer, and
a second portion excluding the metal layer and including the graphene layer.

6. The composite electrode of claim 5, wherein the metal layer includes a transition metal.

7. The composite electrode of claim 5, wherein the graphene layer includes single-layer graphene, bi-layer graphene, tri-layer graphene, few-layer graphene, or multi-layer graphene.

8. The composite electrode of claim 5, further including a gap to separate the composite electrode and another composite electrode located in parallel on a same plane.

9. The composite electrode of claim 5, further including a flexible substrate attached to the composite electrode.

10. The composite electrode of claim 5, further including a processor coupled with the composite electrode to form a computing device.

11. The composite electrode of claim 5, wherein the composite electrode is to form a touch screen of a computing device.

12. The composite electrode of claim 11, wherein the touch screen is to include a flexible touch screen.

13. The composite electrode of claim 5, wherein the composite electrode is to provide a sheet resistance of about 1 ohm/square to about 10 ohm/square and a transmittance of at least about 90%.

14. At least one computer readable storage medium comprising a set of instructions, which when executed by a device, cause the device to:
deposit an adhesion layer on a carrier substrate;
deposit an exfoliation layer on the adhesion layer;
deposit a thermal insulation layer on the exfoliation layer;
generate a crack layer on the thermal insulation layer;
deposit a metal layer on the crack layer;
remove the crack layer; and
grow a graphene layer on the metal layer to generate a sensor film including a random network of metal lines interconnected by graphene.

15. The at least one computer readable storage medium of claim 14, wherein the instructions, when executed, cause the device to:
deposit a silicon-based adhesion layer on a glass carrier substrate;
deposit an amorphous silicon layer on the silicon-based adhesion layer;
deposit a silicon oxide layer on the amorphous silicon layer;
deposit an acrylic layer on the silicon oxide layer; and
deposit a transition metal on the acrylic layer.

16. The at least one computer readable storage medium of claim 15, wherein the instructions, when executed, cause the device to:
implement plasma enhanced chemical vapor deposition (PECVD) to provide one or more of the silicon-based adhesion layer, the amorphous silicon layer, the silicon oxide layer, or the graphene layer at a temperate of less than about 500° C.;
implement lithography-free micro patterning to deposit and dry an acrylic colloidal dispersion on the silicon oxide layer to form the acrylic layer including a random network of grooves that expose the silicon oxide layer;
implement vacuum sputtering to deposit the transition metal on the acrylic layer; and
implement wet chemical etching using chloroform to remove the acrylic layer.

17. The at least one computer readable storage medium of claim 15, wherein the glass carrier substrate has a surface area of about 1.4 m by about 1.2 m, the silicon-based adhesion layer has a thickness of about 10 nm to about 100 nm, the amorphous silicon layer has a thickness of about 100 nm to about 300 nm, the silicon oxide layer has a thickness of at least about 1000 nm, the acrylic layer has a crack including a thickness greater than a thickness of the metal layer, the metal layer has a thickness of less than about 100 nm, and the graphene layer includes single-layer graphene, bi-layer graphene, tri-layer graphene, few-layer graphene, or multi-layer graphene.

18. The at least one computer readable storage medium of claim 15, wherein the metal layer includes copper or nickel, and wherein the silicon-based adhesion layer includes silicon oxide or silicon nitride.

19. The at least one computer readable storage medium of claim 14, wherein the instructions, when executed, cause the device to:
deposit a flexible substrate on the sensor film;
separate the thermal insulation layer from the exfoliation layer; and
remove the thermal insulation layer from the sensor film.

20. The at least one computer readable storage medium of claim 19, wherein the instructions, when executed, cause the device to implement laser lift off to heat the exfoliation layer and separate the thermal insulation layer.

21. The at least one computer readable storage medium of claim 19, wherein the instructions, when executed, cause the device to:
implement wet chemical synthesis or physical vacuum deposition to deposit polyester, polyethylene napthalate, or polyimide on the sensor film; and
implement wet chemical etching using dilute hydrofluoric acid to remove the thermal insulation layer.

22. The at least one computer readable storage medium of claim 14, wherein the instructions, when executed, cause the device to define a composite electrode from the sensor film.

23. The at least one computer readable storage medium of claim 22, wherein the instructions, when executed, cause the device to implement O₂ plasma etching and wet chemical etching to define the composite electrode from the sensor film.

24. The at least one computer readable storage medium of claim 22, wherein the instructions, when executed, cause the device to form a gap to separate the composite electrode from another composite electrode located in parallel on a same plane.

25. The at least one computer readable storage medium of claim 14, wherein the instructions, when executed, cause the device to couple a processor with a portion of the sensor film to form a computing device.

26. The at least one computer readable storage medium of claim 14, wherein one or more of the sensor film or the composite electrode is to provide a sheet resistance of about 1 ohm/square to about 10 ohm/square and a transmittance of at least about 90%.

27. A method comprising:
depositing an adhesion layer on a carrier substrate;
depositing an exfoliation layer on the adhesion layer;
depositing a thermal insulation layer on the exfoliation layer;
generating a crack layer on the thermal insulation layer;
depositing a metal layer on the crack layer;
removing the crack layer; and
growing a graphene layer on the metal layer to generate a sensor film including a random network of metal lines interconnected by graphene.
